(19) United States
(12) Patent Application Publication
(10) Pub. No.: US 2012/0103384 A1
(43) Pub. Date: May 3, 2012

(54) INFORMATION INPUT MODULE AND ELECTRONIC DEVICE USING THE SAME

(75) Inventors: KUAN-HONG HSIEH, Tu-Cheng (TW); HAN-CHE WANG, Tu-Cheng (TW); CHIU-HSIUNG LIN, Tu-Cheng (TW); PO-FU CHENG, Tu-Cheng (TW); BIN-GANG DUAN, Shenzhen City (CN); MING-CHOU CHANG, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/100,298

(22) Filed: May 3, 2011

(30) Foreign Application Priority Data
Oct. 29, 2010 (CN) 201010525020.2

(51) Int. Cl. H01L 31/042

(52) U.S. Cl. 136/244

(57) ABSTRACT

An information input module for an electronic device includes a substrate, a first electrode made up of transparent conductive materials, a second electrode, and a solar cell layer disposed between the first and second electrodes. The solar cell layer includes a plurality of solar cells electrically insulated from each other. The plurality of solar cells generates electrical signals in response to a user's operations to activate functions of the electronic device. The first electrode is disposed between the substrate and the solar cell layer. Both the first and second electrodes are electrically connected to each of the plurality of solar cells for transmitting the electrical signals to the electronic device. The electrical signals reflect changes of electrical parameters of one or more solar cells of the plurality of solar cells when light beams are blocked from reaching on, wholly or partially, the one or more solar cells.

### BACKGROUND

1. Technical Field

The present disclosure relates to an information input module and an electronic device using the same.

2. Description of Related Art

With the progress of science and technology, new materials for converting light energy to electrical energy are developed and energy conversion efficiencies of the new materials have been significantly improved. The new materials are applied on top surfaces of electronic devices to collect solar energy and/or ambient light energy for converting the solar energy and/or ambient light energy to electrical energy. The new materials are mounted at different isolated areas of the top surface. When an area is shielded by the user for operating on the electronic device, the energy conversion efficiency of the area is reduced. However, the area shielded by the user is idle and not sufficiently used since it cannot collect solar energy and/or ambient energy when being shielded.

Therefore, what is needed is an information input module and an electronic device using the same to alleviate the limitations described above.

### BRIEF DESCRIPTION OF THE DRAWINGS

The components in the drawings are not necessarily drawn to scale, the emphasis instead being placed upon clearly illustrating the principles of an information input module and an electronic device using the same. Moreover, in the drawings, like reference numerals designate corresponding sections throughout the several views.

FIG. 1 is a schematic view of an information input module in accordance with an exemplary embodiment.

FIG. 2 is a schematic view of an information input module in accordance with another exemplary embodiment.

FIG. 3 is a schematic view of an electronic device using the information input module, such as the one of FIG. 1, in accordance with the exemplary embodiment.

FIG. 4 is a block diagram of the electronic device of FIG. 3.

### DETAILED DESCRIPTION

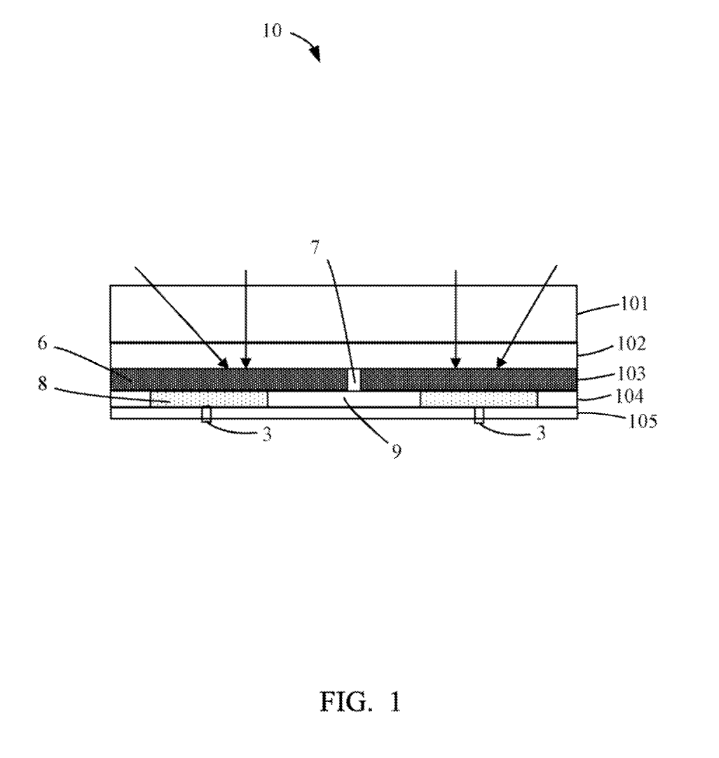

Referring to FIG. 1, an information input module 10 is disclosed as an exemplary embodiment. The information input module 10 includes a transparent substrate 101, a first electrode 102, a solar cell layer 103, a second electrode 104, and a protection layer 105. The information input module 10 is used as input interfaces for various electronic devices, such as input keyboards of mobile phones, electronic readers and PDAs. The information input module 10 is also used for collecting light energies such as solar energy and/or ambient light energy, and converting the collected light energies to electrical energy.

The transparent substrate 101 is made up of glass material or plastic material with good light transmittance.

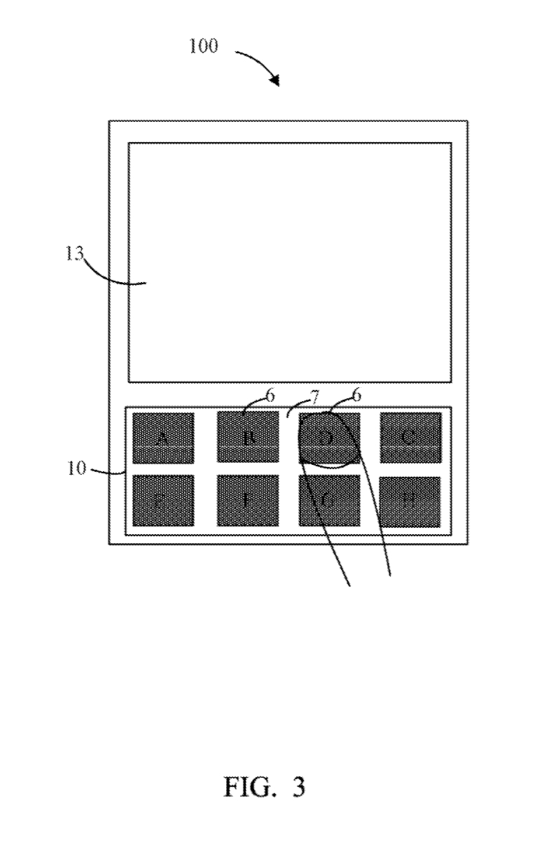

The solar cell layer 103 is disposed between the transparent substrate 101 and the protection layer 105. The solar cell layer 103 includes a number of solar cells 6 electrically insulated from each other, and an isolating area 7 configured for isolating the solar cells 6 from each other. Each of the solar cells 6 corresponds to at least one control command for activating at least one function of the electronic device 100 (See FIG. 3), and generates electrical signals in response to user's operations to activate the function.

In the embodiment, the solar cells 6 are made up of materials such as amorphous silicon, monocrystalline silicon, polycrystalline silicon, or organic silicon, and are coated and lattice shaped on the transparent substrate 101 via industrial coating technology. A plurality of command characters are allocated correspondingly on the solar cells 6 and are etched on the portions of the light incident surface of the transparent substrate 101 respectively with a laser.

Both the first and second electrodes 102, 104 are electrically connected to the solar cells 6. In the embodiment, both the first and second electrodes 102, 104 are layered, and the solar cell layer 103 is disposed between the first and second electrodes 102, 104.

The first electrode 102 is disposed between the transparent substrate 101 and the solar cell layer 103. The first electrode 102 is made up of transparent conductive materials such as indium tin oxide (ITO) film, and electrically connected to one terminal of each of the solar cells 6 to serve as the common electrode of the solar cells 6.

The second electrode 104 includes a number of conductive electrodes 8 and an insulating area 9 configured for electrically isolating the number of conductive electrodes 8 from each other. The conductive electrodes 8 are electrically connected to the other terminals of the solar cells 6 correspondingly, and transmit the electrical parameters of the solar cells 6 to the electronic device 100 via connection to the external wires by at least one conductive column 3.

The protection layer 105 is configured for fixing the first electrode 102, the solar cell layer 103 and the second electrode 104 on the transparent subtract 101.

With such configuration, when an area of the transparent substrate 101 is shielded, the solar light beams and/or ambient light beams are blocked from reaching on, wholly or partially, the solar cell 6 corresponding to the shielded area, thus the voltage, the current, the energy conversion efficiency and other electrical parameters of the solar cell 6 change accordingly. The electronic device 100 outputs control commands corresponding to the changes of the electrical parameters of the solar cell 6 to the corresponding function. Thus, the solar cell 6 is used also used as an input unit.

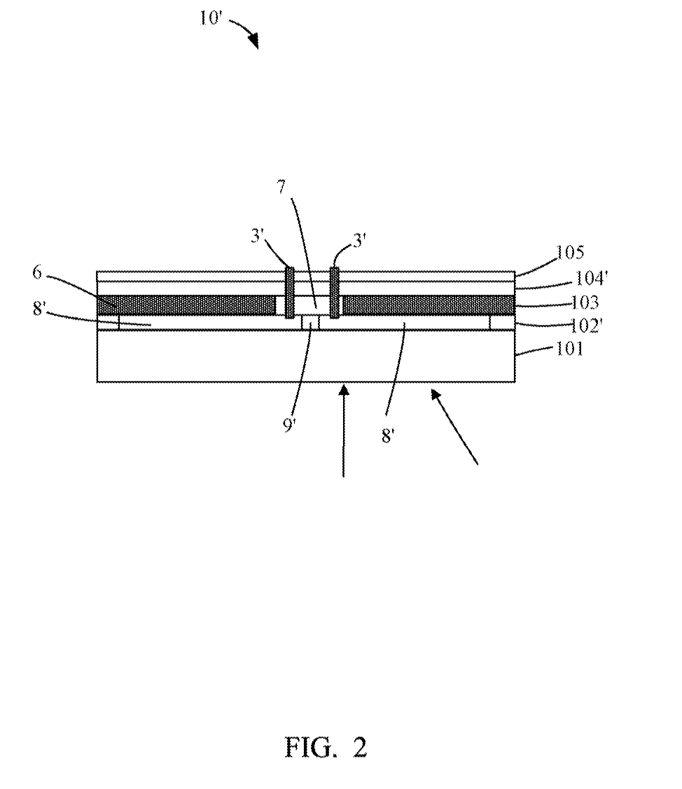

Referring to FIG. 2, an information input module 10′ is disclosed as another exemplary embodiment. Only the differences between the two embodiments will be described, and the other details are omitted. The first electrode 102′ includes a number of transparent conductive electrodes 8′ and an insulating area 9′ configured for electrically isolating the conductive electrodes 8′ from each other. Each of the conductive electrodes 8′ is electrically connected to one terminal of each of the solar cells 6 correspondingly, and transmits the electrical parameters of the solar cells 6 to the electronic device 100 via connection to the external wires by at least one conductive columns 3′. The second electrode 104′ is electrically connected to the other terminal of each of the solar cells 6 to sever as the common electrode of the solar cells 6.

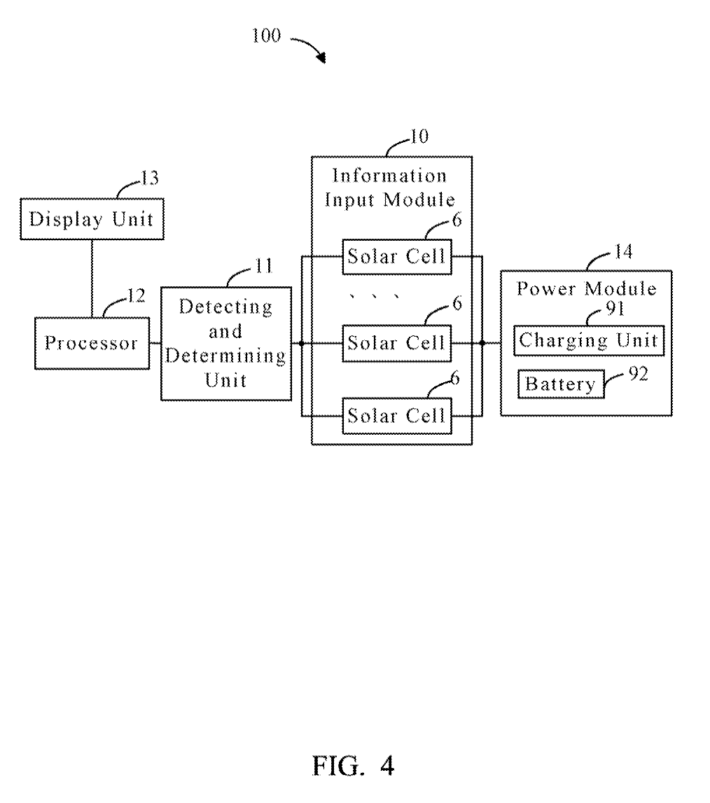

Referring to FIGS. 3 and 4, the electronic device 100 includes the information input module 10 or 10′, a detecting and determining unit 11, a processor 12, a display unit 13 and a power module 14 supplying power to the electronic device 100. The information input module 10 includes a number of insulated solar cells 6. The display unit 13 is an LCD display or an electronic paper display. The detecting and determining unit 11 is configured for detecting the electrical parameters of the number of the solar cells 6, and determining whose electrical parameters are changed. The power module 14 includes a charging unit 91 and a battery 92. The charging unit 91 collects the electrical power generated by the solar cells 6 to charge the battery 92, which extends the standby time of the electronic device 100.

Referring to FIG. 3, in the embodiment, a solar cell 6 labeled with “D” is shielded by a finger of the user, and part of the solar cell 6 labeled with “G” is also shielded. The detecting and determining unit 11 detects the electrical parameters of all of the solar cells 6. Both the electrical parameters of the shielded solar cell 6 and the partially shielded solar cell 6 change, and the electrical parameters of the other solar cells 6 remain a normal status. The detecting and determining unit 11 determines the electrical parameters of the solar cells 6 labeled with “G” and “D” change, and transmits the electrical parameters to the processor 12.

The processor 12 compares the electrical parameters of the solar cells 6, and executes the control command of the solar cell 6 which has the lowest electrical parameter value. In the embodiment, the processor 12 only compares the electrical parameters of the solar cells 6 whose electrical parameters have changed, which reduces the burden on the processor 12 and speeds up the response to the operation of the user.

In an alternative embodiment, the processor 12 stores a plurality of control commands corresponding to the conditions that the electrical parameters of at least two of the solar cells 6 change at a same time. The processor 12 retrieves the corresponding control command, when the electrical parameters of at least two solar cells 6 change at a same time, and executes the control command, thus achieving a multi touch function. The processor 12 executes the control command correspondingly to the solar cell 6 which has the lowest electrical parameter value or ignores the operation, when no control command is stored to correspond to the condition that the electrical parameters of the at least two solar cells 6 change at a same time.

The electronic device 100 includes the information input module 10 with converting light energy to electrical energy function, thus sufficiently uses the solar light and/or ambient light, and achieves an additional information input function.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. An information input module for an electronic device, comprising:
a substrate;
a first electrode made up of conductive materials;
a second electrode; and
a solar cell layer disposed between the first and second electrodes, comprising a plurality of solar cells electrically insulated from each other, the plurality of solar cells generating electrical signals in response to a user's operations to activate functions of the electronic device;
wherein the first electrode is disposed between the transparent substrate and the solar cell layer, both the first and second electrodes are electrically connected to each of the plurality of solar cells and for transmitting the electrical signals to the electronic device, the electrical signals reflect changes of electrical parameters of one or more solar cells of the plurality of solar cells when light beams are blocked from reaching on, wholly or partially, the one or more solar cells.

2. The information input module as described in claim 1, wherein the first electrode is made up of transparent conductive materials.

3. The information input module as described in claim 1, wherein the substrate is transparent, and made of glass material or plastic material with good light transmittance.

4. The information input module as described in claim 3, wherein the solar cell layer further comprises an isolating area configured for isolating the solar cells from each other.

5. The information input module as described in claim 3, wherein the plurality of solar cells are made up of materials selected from the group consisting of amorphous silicon, monocrystalline silicon, polycrystalline silicon, and organic silicon.

6. The information input module as described in claim 5, wherein the plurality of solar cells are coated and lattice shaped on the substrate via industrial coating technology.

7. The information input module as described in claim 5, wherein the both the first and second electrodes are layered, the first electrode is electrically connected to one terminal of each of the plurality of solar cells to serve as a common electrode of the plurality of the solar cells, and the second electrode comprises a plurality of conductive electrodes electrically connected to the other terminals of the plurality of the solar cells correspondingly.

8. The information input module as described in claim 5, wherein both the first and second electrodes are layered, the second electrode is electrically connected to one terminal of each of the plurality of solar cells to form a common electrode of the plurality of the solar cells, and the first electrode comprises a plurality of conductive electrodes electrically connected to the other terminals of the plurality of the solar cells correspondingly.

9. The information input module as described in claim 7, wherein the second electrode further comprises an insulating area configured for electrically isolating the plurality of conductive electrodes from each other.

10. The information input module as described in claim 3, wherein a plurality of command characters are allocated correspondingly on the plurality of solar cells, and are etched on a light incident surface of the substrate respectively.

11. The information input module as described in claim 2, the first electrode is made up of indium tin oxide film.

12. An electronic device, comprising:
an information input module, comprising:
a substrate;
a first electrode made up of conductive materials;
a second electrode; and
a solar cell layer disposed between the first and second electrodes, comprising a plurality of solar cells electrically insulated from each other, the plurality of solar cells generating electrical signals in response to a user's operations to activate functions of the electronic device;
wherein the first electrode is disposed between the substrate and the solar cell layer, both the first and second electrodes are electrically connected to each of the plurality of solar cells and for transmitting the electrical signals to the electronic device, the electrical signals reflect changes of electrical parameters of one or more solar cells of the plurality of solar cells when light beams are blocked from reaching on, wholly or partially, the one or more solar cells;
a detecting and determining unit configured for detecting the electrical parameters of the plurality of the solar cells, and determining whose electrical parameters are changed; and
a processor comparing the electrical parameters of the plurality of solar cells whose electrical parameters have changed, and executing a control command of one of the plurality of the solar cells which has a lowest electrical parameter value.

13. The electronic device as described in claim 12, wherein the substrate is transparent, and made of glass material or plastic material with good light transmittance.

14. The electronic device as described in claim 13, wherein the plurality of solar cells are made up of materials selected from the group consisting of amorphous silicon, monocrystalline silicon, polycrystalline silicon, and organic silicon.

15. The electronic device as described in claim 14, wherein the electronic device further comprises a power module configured for collecting electricity power generated by the plurality of solar cells.

16. The electronic device as described in claim 13, wherein a plurality of command characters are allocated correspondingly on the plurality of solar cells, and are etched on a light incident surface of the substrate respectively.

17. An electronic device, comprising:
an information input module, comprising:
a substrate;
a first electrode made up of conductive materials;
a second electrode; and
a solar cell layer disposed between the first and second electrodes, comprising a plurality of solar cells electrically insulated from each other, the plurality of solar cells generating electrical signals in response to a user's operations to activate functions of the electronic device;
wherein the first electrode is disposed between the substrate and the solar cell layer, both the first and second electrodes are electrically connected to each of the plurality of solar cells, and for transmitting the electrical signals to the electronic device, the electrical signals reflect changes of electrical parameters of one or more solar cells of the plurality of solar cells when light beams are blocked from reaching on, wholly or partially, the one or more solar cells;
a detecting and determining unit configured for detecting the electrical parameters of the plurality of the solar cells, and determining whose electrical parameters are changed; and
a processor storing a plurality of control commands corresponding to conditions that the electrical parameters of at least two of the solar cells change simultaneously, and the processor configured for determining whether the electrical parameters of at least two of the plurality of solar cells have changed simultaneously, and retrieving and executing a control command corresponding to the condition of the at least two of the solar cells whose electrical parameters have changed simultaneously.

18. The electronic device as described in claim 17, wherein the processor executes the control command of one of the at least two of the plurality of the solar cells which has a lowest electrical parameter value, when no control command is stored to correspond to the condition that the electrical parameters of the at least two solar cells change simultaneously.

19. The electronic device as described in claim 18, wherein the substrate is made up of glass material or plastic material with good light transmittance.

20. The electronic device as described in claim 19, wherein the electronic device further comprises a power module configured for collecting electricity power generated by the plurality of solar cells.
